(19) United States
(12) Patent Application Publication
(10) Pub. No.: US 2023/0307592 A1
(43) Pub. Date: Sep. 28, 2023

(54) DISPLAY PANEL, MANUFACTURING METHOD THEREFOR AND DISPLAY DEVICE

(71) Applicant: TIANMA ADVANCED DISPLAY TECHNOLOGY INSTITUTE (XIAMEN) CO., LTD., Xiamen (CN)

(72) Inventors: Feng QIN, Shanghai (CN); Yingteng ZHAI, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/324,167

(22) Filed: May 26, 2023

(30) Foreign Application Priority Data
Mar. 31, 2023 (CN) 202310341245.X

(51) Int. Cl. H01L 33/58; H01L 25/075; H01L 33/62

(52) U.S. Cl. CPC H01L 33/58; H01L 25/0753; H01L 33/62; H01L 2933/0058

(57) ABSTRACT

A display panel, a manufacturing method therefor and a display device are provided. The display panel includes: a driving substrate; a light-shielding layer, located on a side of the driving substrate, where the light-shielding layer includes a first shielding structure and a second shielding structure, the first shielding structure includes a first opening, the second shielding structure is located in the first opening, and a thickness of the second shielding structure is less than that of the first shielding structure in a first direction, where the first direction is vertical to a plane where the driving substrate is located and points to a light-emergent surface of the display panel; and multiple pixel units, where the pixel unit includes multiple light-emitting elements located in the first opening, and the driving substrate provides driving signals for the light-emitting elements.

This application claims priority to Chinese Patent Application No. 202310341245.X, titled “DISPLAY PANEL, MANUFACTURING METHOD THEREFOR AND DISPLAY DEVICE”, filed on Mar. 31, 2023, with the China National Intellectual Property Administration, which is hereby incorporated by reference in its entirety.

### FIELD

The present disclosure relates to the field of display technology, and more particularly, to a display panel, a manufacturing method therefor, and a display device.

### BACKGROUND

Light-emitting elements such as organic light-emitting diodes (OLEDs), mini light-emitting diodes (mini LEDs), micro light-emitting diodes (micro LEDs) are widely used in the field of display technology.

In order to better drive the light-emitting elements to emit light to realize display, a driving substrate for controlling the light-emitting elements is provided. In the conventional display panels, the overall reflectivity of the display panel is relatively high due to defects in the structural design, which affects the display effect.

### SUMMARY

A display panel, a manufacturing method therefor and a display device are provided according to embodiments of the present disclosure, which can reduce the reflectivity and ensure the display effect.

In one embodiment, a display panel is provided according to the present disclosure, which includes: a driving substrate; a light-shielding layer, located on a side of the driving substrate, where the light-shielding layer includes a first shielding structure and a second shielding structure, the first shielding structure includes a first opening, the second shielding structure is located in the first opening, and a thickness of the second shielding structure is less than that of the first shielding structure in a first direction, where the first direction is vertical to a plane where the driving substrate is located and points to a light-emergent surface of the display panel; and multiple pixel units, where the pixel unit include multiple light-emitting elements, the light-emitting element is located in the first opening, and the driving substrate provides driving signals for the light-emitting elements.

In another embodiment, a method for manufacturing a display panel is provided according to the present disclosure, which includes:
forming a light-shielding layer on a side of a driving substrate, where the light-shielding layer includes a first shielding structure and a second shielding structure, the first shielding structure includes a first opening, the second shielding structure is located in the first opening, and a thickness of the second shielding structure is less than that of the first shielding structure in a first direction, where the first direction is vertical to a plane where the driving substrate is located and points to a light-emergent surface of the display panel; and
bonding light-emitting elements, where at least a portion of the light-emitting element is passed through the light-shielding layer and coupled to the driving substrate to form the display panel, where the light-emitting element is located in the first opening.

In yet another embodiment, a display device is provided according to the present disclosure, which includes the above display panel.

According to the present disclosure, a display panel, a manufacturing method therefor and a display device are provided. The display panel includes a driving substrate, a light-shielding layer, and multiple pixel units. The light-shielding layer can be located on a side of the driving substrate, and includes a first shielding structure and a second shielding structure. The second shielding structure is located in the first opening of the first shielding structure. Multiple light-emitting elements of the pixel unit are disposed in the first opening, and the driving substrate can provide driving signals for the light-emitting elements, to control the light-emitting elements to meet display requirements. Since the second shielding structure and the light-emitting elements are disposed in the first opening, the regions between the light-emitting elements can be light-shielded through the first shielding structure. In addition, the regions where the light-emitting elements are located can be light-shielded through the second shielding structure, to reduce the overall reflectivity of the display panel and ensuring the display effect.

### BRIEF DESCRIPTION OF THE DRAWINGS

Embodiments of the present disclosure will be described below with reference to the accompanying drawings.

FIG. 1 is a top view of a display panel according to an embodiment of the present disclosure;

FIG. 2 is a section view in an A-A direction shown in FIG. 1;

FIG. 3 is a section view of a display panel according to another embodiment of the present disclosure;

FIG. 4 is a section view of a display panel according to yet another embodiment of the present disclosure;

FIG. 5 is a section view of a display panel according to still another embodiment of the present disclosure;

FIG. 6 is a section view of a display panel according to yet another embodiment of the present disclosure;

FIG. 7 is a top view of a display panel according to yet another embodiment of the present disclosure;

FIG. 8 is a section view in a B-B direction shown in FIG. 7;

FIG. 9 is a top view of a display panel according to still another embodiment of the present disclosure;

FIG. 10 is a section view in a C-C direction shown in FIG. 9;

FIG. 11 is a top view of a display panel according to yet another embodiment of the present disclosure;

FIG. 12 is a top view of a display panel according to still another embodiment of the present disclosure;

FIG. 13 is a section view in a D-D direction shown in FIG. 12;

FIG. 14 is a section view of a display panel according to another embodiment of the present disclosure;

FIG. 15 is a flowchart of a method for manufacturing a display panel according to an embodiment of the present disclosure;

FIGS. 16 to 18 are schematic structural diagrams corresponding to steps of a method for manufacturing a display panel according to an embodiment of the present disclosure;

FIGS. 19 to 20 are schematic structural diagrams corresponding to step S100 in a method for manufacturing a display panel according to an embodiment of the present disclosure; and

FIGS. 21 to 22 are schematic structural diagrams corresponding to step S100 in a method for manufacturing a display panel according to another embodiment of the present disclosure.

In the drawings:
10: Driving substrate; 11: Bonding terminal;
20: Light-shielding layer; 21: First shielding structure; 211: First opening; 22: Second shielding structure; 221: Second opening; 222: Third opening;
30: Pixel unit; 31: Light-emitting element; 311: Light-emitting body; 312: Connection terminal; 312a: First end surface; 312b: Second end surface; 31a: First-color light-emitting element; 31b: Second-color light-emitting element; 31c: Third-color light-emitting element;
40: Barrier layer;
50: Base layer;
X: First direction.

In the drawings, the same parts are given the same reference signs. The drawings are not drawn to scale.

### DETAILED DESCRIPTION OF EMBODIMENTS

Embodiments of the present disclosure are further described in detail below in conjunction with the drawings and some embodiments. It should be noted that the some embodiments described here are only intended to explain the present disclosure, rather than to limit the present disclosure. Embodiments of the present disclosure can be practiced without some of these specific details. The following description of the embodiments is only to provide a better understanding of the present disclosure by showing examples thereof.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, method, article or device. Unless expressively limited, the statement “including a . . . ” does not exclude the case that other similar elements may exist in the process, method, article or device, other than enumerated elements.

It should be understood that, when describing the structure of a component, when a layer or a region is referred to as being “on” or “over” another layer or another region, it may be directly on another layer or another region. In one embodiment, other layers or regions may also be included between it and another layer or another region. In addition, if the component is flipped, the layer or the region will be “below” or “beneath” another layer or another region.

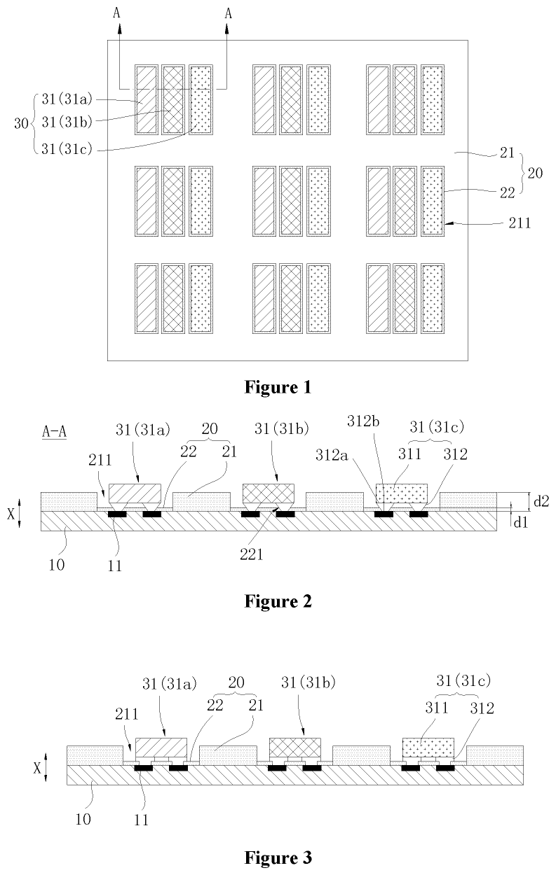

As shown in FIG. 1 and FIG. 2, a display panel is provided according to an embodiment of the present disclosure, which includes: a driving substrate 10, a light-shielding layer 20 and multiple pixel units 30. The light-shielding layer 20 is located on a side of the driving substrate 10, and includes a first shielding structure 21 and a second shielding structure 22. The first shielding structure 21 includes a first opening 211, the second shielding structure 22 is located at the first opening 11, and a thickness d1 of the second shielding structure 22 is less than a thickness d2 of the first shielding structure 21 in a first direction X. The first direction X is vertical to a plane where the driving substrate 10 is located and points to a light-emergent surface of the display panel. The pixel unit 30 includes multiple light-emitting elements 31, the light-emitting element 31 is located in the first opening, and the driving substrate 10 provides driving signals for the light-emitting elements.

In an embodiment, the light-emitting element 31 may include but is not limited to at least one of an organic light-emitting diode (OLED), a mini light-emitting diode (mini LED), and a micro light-emitting diode (micro LED).

The driving substrate 10 may include a substrate and a device layer, and the substrate may be flexible or rigid. The device layer may include multiple pixel driving circuits, and the multiple pixel driving circuits may be coupled to the multiple light-emitting elements 31. The driving substrate 10 provides driving signals for the light-emitting elements 31 to meet the driving requirements for the light-emitting elements 31. In an embodiment, the driving substrate 10 may be provided with bonding terminals 11, through which the driving substrate 10 can be in contact with and coupled to light-emitting elements 31.

The first direction X is vertical to the plane where the driving substrate 10 is located and points to the light-emergent surface of the display panel, which can also be understood as the thickness-wise direction of the driving substrate 10. The light-shielding layer 20 may be disposed on a side of the driving substrate 10 down the first direction X.

The number of first openings 211 included in the first shielding structure 21 may be more than two, and in this case, the more than two first openings 211 are spaced apart from each other. The second shielding structure 22 may be disposed in each first opening 211.

In the first direction X, the shape of the orthographic projection of the first opening 211 may be a circle, an ellipse or a polygon. In case of a polygon, the polygon may be a regular polygon.

The shape of the orthographic projection of the outer periphery of the first shielding structure 21 may match the shape of the orthographic projection of a corresponding first opening 211. For example, in a case that the shape of the orthographic projection of the first shielding structure 21 is a circle, the shape of the first opening 211 may also be a circle with the same radial dimension.

The thickness d1 of the second shielding structure 22 is less than the thickness d2 of the first shielding structure 21, where the first shielding structure 21 may be flush or approximately flush with the second shielding structure 22 on a side facing the driving substrate 10 in the first direction X, and protrude from the second shielding structure 22 on a side facing away from the driving substrate 10 in the first direction X.

The number of pixel units 30 may be set according to the size of the display panel, and the number of light-emitting elements 31 included in each pixel unit 30 may be three, four or even more.

In the display panel according to the embodiment of the present disclosure, the light-shielding layer 20 is provided on a side of the driving substrate 10, and includes the first shielding structure 21 and the second shielding structure 22. The second shielding structure 22 is located in the first opening 211 of the first shielding structure 21. Multiple light-emitting elements 31 of the pixel unit 30 are disposed in the first opening 211, and the driving substrate 10 can provide driving signals for the light-emitting elements 31, to control the light-emitting elements 31 to meet display requirements. Since the second shielding structure 22 and the light-emitting element 31 are disposed in the first opening 211, the regions between the light-emitting elements 31 can be light-shielded through the first shielding structure 21. In addition, the regions where the light-emitting elements 31 are located can be light-shielded through the second shielding structure 22, to reduce the overall reflectivity of the display panel and ensuring the display effect.

In some embodiments, in the display panel according to the embodiment of the present disclosure, the light-emitting element 31 includes a light-emitting body 311 and a connection terminal 312, the second shielding structure 22 includes a second opening 221, the connection terminal 312 is at least partially disposed in the second opening 221 and is electrically connected to the driving substrate 10, and the second shielding structure 22 is at least partially disposed between the light-emitting body 311 and the driving substrate 10.

The connection terminals 312 included in the light-emitting body 311 may be arranged in pairs. In an embodiment, in a case that the connection terminals 312 are arranged in pairs, the polarities of the connection terminals 312 arranged in a pair may be opposite.

The number of second openings 221 in the second shielding structure 22 may be equal to the total number of connection terminals 312 included in the light-emitting elements 31 disposed in the second shielding structure 22. In one embodiment, it may also be more than the total number of connection terminals 312 included in the light-emitting elements 31 disposed in the second shielding structure 22.

The shape of the second opening 221 may match the shape of the connection terminal 312, i.e., the second shielding structure 22 may fit and be in close contact with the outer peripheral surface of the connection terminal 312. In one embodiment, the size of the second opening 221 may be greater than the size of the connection terminal 312, and a gap is formed between the second shielding structure 22 and the outer peripheral surface of the connection terminal 312.

The portion of the second shielding structure 22 located between the light-emitting body 311 and the driving substrate 10 may be in contact with the light-emitting body 311. In one embodiment, a gap may be formed between it and the light-emitting body 311 in the first direction X.

The second opening 221 may be pre-set in the second shielding structure 22 before the light-emitting element 31 is bonded to the driving substrate 10. In one embodiment, the second opening 221 may be formed by piercing the second shielding structure 22 with the connection terminal 312, when the light-emitting element 31 is bonded to the driving substrate 10.

In the display panel according to the embodiment of the present disclosure, the second opening 221 is provided in the second shielding structure 22, to facilitate avoiding the connection terminal 312. The light-emitting element 31 can be coupled to the driving substrate 10 through the connection terminal 312, to ensure the driving substrate 10 can provide drive signals to the light-emitting elements 31. In addition, the second shielding structure 22 is at least partially disposed between the light-emitting body 311 and the driving substrate 10, to increase the coverage area of the light shielding layer 20 on the driving substrate 10. In this way, the reflectivity can be effectively reduced and the display effect can be optimized.

As shown in FIG. 2, in some embodiments, in the display panel according to the embodiment of the present disclosure, the connection terminal 312 has a first end surface 312a and a second end surface 312b opposite to each other in the first direction X. The first end surface 312a is connected to the driving substrate 10 and the second end surface 312b is connected to the light-emitting body 311, and the area of the cross section of the connection terminal 312 increases in the first direction.

In the first direction X, the area of the orthographic projection of the first end surface 312a is less than the area of the orthographic projection of the second end surface 312b. The shape of the orthographic projection of the first end surface 312a may be the same as the shape of the orthographic projection of the second end surface 312b. For example, the first end surface 312a and the second end surface 312b both may be circular. In one embodiment, the first end surface 312a and the second end surface 312 both may be polygonal. In addition, the shape of the orthographic projection of the first end surface 312a and that of the second end surface 312b may be different. For example, one of the orthographic projections of the first end surface 312a and the second end surface 312b may be circular and the other may be polygonal.

With the display panel according to the embodiment of the present disclosure, the area of the cross section of the connection terminal 312 increases in the first direction X, and the connection terminal 312 has a shape with a wide top and a narrow bottom, i.e., forming a sharp tip on the side facing the driving substrate 10. When the light-emitting element 31 is bonded to the driving substrate 10, the connection terminal 312 in this form can be bonded and coupled to the driving substrate 10 after directly piercing through the second shielding structure 22, which can not only meet the requirements of coupling connection with the driving substrate 10 to reduce the reflectivity, but also simplify the manufacturing process of the display panel.

As shown in FIG. 2, in some embodiments, in the display panel according to the embodiment of the present disclosure, the area of the cross section of the connection terminal 312 increases gradually in the first direction X.

In other words, the connection terminal 312 as a whole may be in a cone shape, a circular cone shape, or a pyramid shape.

In the display panel according to the embodiment of the present disclosure, with the connection terminal 312 in the above form, a sharp tip is formed on the side facing the driving substrate 10, which facilitates the piercing of the second shielding structure 22 when the connection terminal 312 is bonded and coupled to the driving substrate 10, reducing the difficulty of bonding.

One embodiment that the area of the cross section of the connection terminal 312 increases gradually in the first direction X.

As shown in FIG. 3, in some embodiments, the area of the cross section of the connection terminal 312 may increase in a piecewise manner in the first direction X.

Put it another way, the connection terminal 312 as a whole may be in a step-like shape, and the cross section thereof on a side facing the driving substrate 10 is smaller. In this way, a sharp tip with a relatively small cross-sectional size can also be formed on the side facing the driving substrate 10, which can realize the piercing of the second shielding structure 22 when the connection terminal 312 is bonded and coupled to the driving substrate 10, reducing the difficulty of bonding.

It can be understood that the display panel according to the above embodiments of the present disclosure, in which the area of the cross section of the connection terminal 312 increases in the first direction X, is described for example; the above are merely some embodiments, while the present disclosure is not limited thereto.

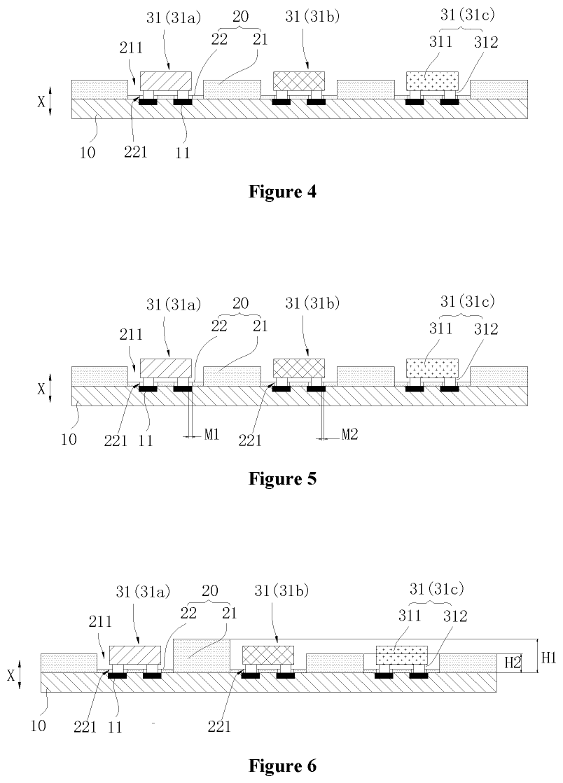

As shown in FIG. 4, in some embodiments, in the connection terminal 312 of the display panel according to the embodiment of the present disclosure, the first end surface 312a is connected to the driving substrate 10 and the second end surface 312b is connected to the light-emitting body 311 in the first direction X, and the connection terminal 312 is a structure with a constant cross section from the first end surface 312a to the second end surface 312b in the thickness-wise direction.

In the first direction X, the area of the orthographic projection of the first end surface 312a may be equal to the area of the orthographic projection of the second end surface 312b. Accordingly, the shape of the orthographic projection of the first end surface 312a may be the same as the shape of the orthographic projection of the second end surface 312b. The first end surface 312a and the second end surface 312b both may be circular. In one embodiment, the first end surface 312a and the second end surface 312b both may be polygonal.

In the display panel according to the embodiment of the present disclosure, in a case that the connection terminal 312 is a structure with constant cross section, before the light-emitting element 31 is bonded to the driving substrate 10, the corresponding second opening 221 can be pre-set in the second shielding structure 22, and the connection terminal 312 can be at least partially located in the second opening 221 and bonded and coupled to the driving substrate 10. The connection terminal 312 with the above structure can also meet the requirements of coupling connection with the driving substrate 10, and ensure that the second shielding structure 22 is at least partially disposed between the light-emitting body 311 and the driving substrate 10 to reduce reflectivity.

As shown in FIGS. 2 and 3, in some embodiments, in the display panel according to the above-mentioned embodiments of the present disclosure, the aperture diameter of the second opening 221 may be equal to the outer diameter of the connection terminal 312. In other words, the wall surface of the second shielding structure 22 enclosing the second opening 221 is in close contact with the connection terminal 312, and no gap is formed between them. The above arrangement can reduce the reflectivity of the driving substrate 10 to the light and ensure the display effect.

An embodiment that the aperture diameter of the second opening 221 is equal to the outer diameter of the connection terminal 312, and the present disclosure is not limited thereto.

As shown in FIG. 4, in some embodiments, the aperture diameter of the second opening 221 may be greater than the outer diameter of the connection terminal 312, and a gap is formed between the outer peripheral surface of the connection terminal 312 and the wall surface enclosing the second opening 221. Through the above arrangement, while reducing the light reflectivity of the driving substrate 10, it is also convenient for the connection terminal 312 to be plugged into the second opening 221 and bonded to the driving substrate 10.

As shown in FIG. 5, in some embodiments, in the display panel according to the above embodiments of the present disclosure, the pixel unit 30 may include a first-color light-emitting element 31a and a second-color light-emitting element 31b. A first gap M1 is formed between the first-color light-emitting element 31a and the wall surface of the second opening 221 where the first-color light-emitting element 31a is located, and a second gap M2 is formed between the second-color light-emitting element 31b and the wall surface of the second opening 221 where the second-color light-emitting element 31b is located, where the first gap M1 is greater than the second gap M2.

Exemplarily, the first-color light-emitting element 31a may be a red light-emitting element, and the second-color light-emitting element 31b may be a green light-emitting element. In one embodiment, the first-color light-emitting element 31a may be a green light-emitting element, and the second-color light-emitting element 31b may be a blue light-emitting element. In some embodiments, the first-color light-emitting element 31a may be a red light-emitting element, and the second-color light-emitting element 31b may be a blue light-emitting element.

The first gap may be understood as the minimum width between the first-color light-emitting element 31a and the wall surface of the second opening 221 where the first-color light-emitting element 31a is located.

The second gap may be understood as the minimum width between the second-color light-emitting element 31b and the wall surface of the second opening 221 where the second-color light-emitting element 31b is located.

In the display panel according to the embodiment of the present disclosure, according to the light-emitting requirements, the light-emitting elements 31 of different colors may have different size proportions. In a case that the light-emitting elements 31 of different colors have different sizes according to the light-emitting requirements, by defining the first gap M1 is larger than the second gap M2, the sizes of the second openings 221 can be made the same. When the second openings 221 are preset on the light-shielding layer 20 before the light-shielding element 31 is bonded to the driving substrate 10, the specifications and sizes of the second openings 221 can be the same, which facilitates forming the second openings 221 in one process.

In some embodiments, in the display panel according to the embodiment of the present disclosure, in the first direction X, the ratio of the thickness of the connection terminal 312 to the thickness of the second shielding structure 22 is greater than 1.

In the first direction X, the ratio of the thickness of the connection terminal 312 to the thickness of the second shielding structure 22 may be any value in a range from 1 to 2, including the endpoint value 2.

In the display panel according to the embodiment of the present disclosure, by configuring the ratio of the thickness of the connection terminal 312 to the thickness of the second shielding structure 22 greater than 1, it can ensure that the thickness of the connection terminal 312 in the first direction X is greater than that of the second shielding structure 22 in the first direction X. In a case that the thickness of the second shielding structure 22 has a slight deviation during the manufacturing process, the portion of the connection terminal 312 higher than the second shielding structure 22 can make up for the deviation during the manufacturing process, meeting the bonding requirement of the light-emitting element 31 and the driving substrate 10, to ensure the stability of the coupling connection therebetween.

As shown in FIG. 1 to FIG. 5, in some embodiments, in the display panel according to the embodiment of the present disclosure, a single light-emitting element 31 is disposed in the first opening 211.

The number of the first openings 211 may be equal to the total number of the light-emitting elements 31 included in the pixel units 30. The first openings 211 and the light-emitting elements 31 are disposed in one-to-one correspondence, and each first opening 211 is provided with one light-emitting element 31.

Exemplarily, the light-emitting element 31 located in each first opening 211 may be one of a red light-emitting element, a blue light-emitting element, a green light-emitting element, and a white light-emitting element.

In the display panel according to the embodiment of the present disclosure, by disposing a single light-emitting element 31 in the first opening 211, each light-emitting element 31 can be disposed separately from one another, which can reduce the probability of optical crosstalk between different light-emitting elements 31 and ensure the display effect.

As shown in FIG. 6, in some embodiments, in the display panel according to the embodiment of the present disclosure, the pixel unit 30 includes a first-color light-emitting element 31a, a second-color light-emitting element 31b and a third-color light-emitting element 31c. In the first direction X, a portion of the first shielding structure 21 located between the first-color light-emitting element 31a and the second-color light-emitting element 31b has a first height H1, and a portion of the first shielding structure 21 located between the second-color light-emitting element 31b and the third-color light-emitting element 31c has a second height H2, where the first height H1 is greater than the second height H2.

Exemplarily, the first-color light-emitting element 31a may be a red light-emitting element, the second-color light-emitting element 31b may be a green light-emitting element, and the third-color light-emitting element 31c may be a blue light-emitting element. In the first direction X, the portion of the first shielding structure 21 located between the red light-emitting element and the green light-emitting element has a first height, the portion of the first shielding structure 21 located between the green light-emitting element and the blue light-emitting element has a second height, and the first height is greater than the second height.

The above example is merely an embodiment. In some alternative examples, the first-color light-emitting element 31a may be a green light-emitting element, the second-color light-emitting element 31b may be a red light-emitting element, and the third-color light-emitting element 31c may be a blue light-emitting element. In the first direction X, the portion of the first shielding structure 21 located between the green light-emitting element and the red light-emitting element has a first height, the portion of the first shielding structure 21 located between the red light-emitting element and the blue light-emitting element has a second height, and the first height is greater than the second height.

The above two examples are only intended for better understanding of the display panel according to the embodiment of the present disclosure, and the present disclosure is not limited to the above examples. The display panel may be configured according to the specific display requirements thereof and optical crosstalk prevention requirements.

In the display panel according to the embodiment of the present disclosure, the portion of the first shielding structure 21 located between the first-color light-emitting element 31a and the second-color light-emitting element 31b is configured with a first height H1 and the portion of the first shielding structure 21 located between the second-color light-emitting element 31b and the third-color light-emitting element 31c is configured with a second height H2, where the first height H1 is greater than the second height H2. The height of the first shielding structure 21 in different regions can be appropriately configured according to the wavelengths of the light from light-emitting elements 31 with different colors and the exit angles of the light after emitted from the light-emitting elements 31. In this way, the height of the first shielding structure 21 can be appropriately configured while fulfilling the requirement of optical crosstalk prevention.

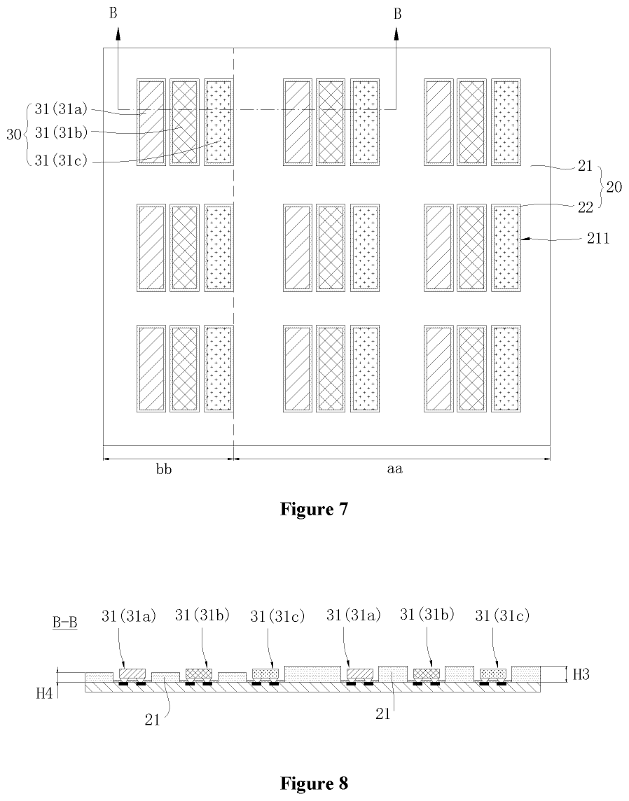

As shown in FIG. 7 and FIG. 8, in some embodiments, the display panel according to the embodiment of the present disclosure has a first region aa and a second region bb, and the pixel unit include a first-color light-emitting element 31a and a second-color light-emitting elements 31b. In the first region aa, the first shielding structure 21 between at least one first-color light-emitting element 31a and an adjacent second-color light-emitting element 31b has a third height H3 in the first direction X, and in the second region bb, the first shielding structure 21 between at least one first-color light-emitting element 31a and an adjacent second-color light-emitting element 31b has a fourth height H4, where the third height H3 is greater than the fourth height H4.

Exemplarily, the first region may be obtained by division according to the distance from the edges of the display panel. For example, the first region may be a marginal region, and the second region may be a central region. The first region may be disposed around the second region, and the distance from the first region to the edges of the display panel is less than the distance from the second region to the edges of the display panel.

Exemplarily, the first region aa and the second region bb can be obtained by division according to the light transmittance. For example, the light transmittance of the first region aa may be greater than the light transmittance of the second region bb, where the first region aa may be a CUP (Camera Under Panel) region.

Exemplarily, the first-color light-emitting element 31a may be a red light-emitting element, and the second-color light-emitting element 31b may be a green light-emitting element. In one embodiment, the first-color light-emitting element 31a may be a green light-emitting element, and the second-color light-emitting element 31b may be a blue light-emitting element. In some embodiments, the first-color light-emitting element 31a may be a red light-emitting element, and the second-color light-emitting element 31b may be a blue light-emitting element.

According to the embodiment of the present disclosure, the display panel may be divided into different regions, and the height of the first shielding structure 21 in a respective one of the regions may be configured according to the functional requirements of that region, which is beneficial to meeting the functional requirements of different regions while reducing the light reflectivity and optical crosstalk rate.

It can be understood that, in the display panel according to the embodiment of the present disclosure, disposing a single light-emitting element 31 in each first opening 211 is merely some embodiments, and the present disclosure is not limited thereto.

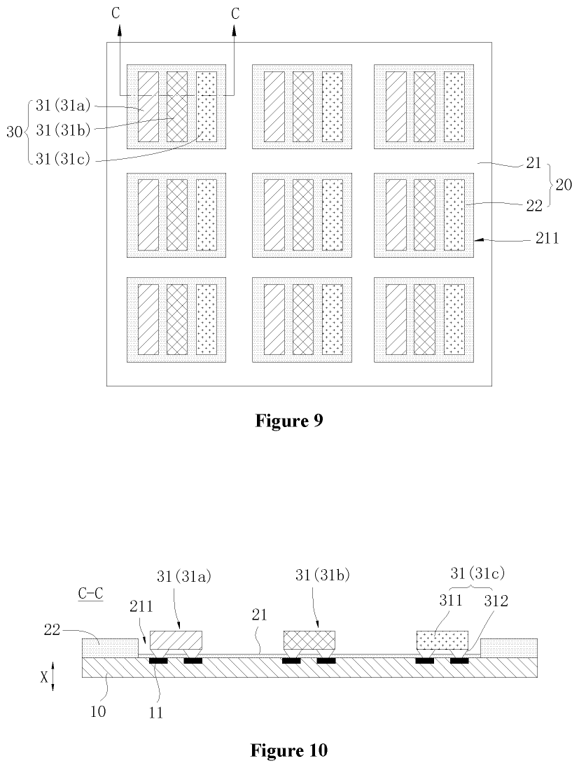

As shown in FIG. 9 and FIG. 10, in some other embodiments, in the display panel according to the embodiment of the present disclosure, at least two light-emitting elements 31 are disposed in the first opening 211.

The number of light-emitting elements 31 disposed in each first opening 211 may be two, three or even more.

The colors of the light-emitting elements 31 located in the same first opening 211 may be the same or different.

More than two light-emitting elements 31 located in each first opening 211 may be at least one of red light-emitting elements, blue light-emitting elements, green light-emitting elements, and white light-emitting elements.

In the display panel according to the embodiment of the present disclosure, by configuring at least two light-emitting elements 31 in each first opening 211, the number of first openings 211 can be reduced and the manufacturing process of the light-shielding layer can be simplified, while reducing the reflectivity.

Further referring to FIG. 9 and FIG. 10, in some embodiments, in the display panel according to the embodiment of the present disclosure, the light-emitting colors of at least two light-emitting elements 31 among the light-emitting elements 31 disposed in the first opening 211 are different.

Exemplarily, the colors of the light-emitting elements 31 located in the same first opening 211 may be different; for example, the light-emitting elements 31 located in the same first opening 211 may include the light-emitting elements 31 in the same pixel unit 30. The light-emitting elements 31 located in the same first opening 211 may include one red light-emitting element, one green light-emitting element and one blue light-emitting element. In one embodiment, the light-emitting elements 31 located in the same opening may include two red light-emitting elements, one green light-emitting element and one blue light-emitting element.

In the display panel according to the embodiment of the present disclosure, by configuring at least two light-emitting elements 31 among the light-emitting elements 31 in the first opening 211 with different light-emitting colors, the light-emitting elements 31 of the same pixel unit 30 can be placed in the same first opening 211. Since the light-emitting elements 31 of the same pixel unit 30 can realize the light-emitting requirement by color mixing, the requirement for the crosstalk rate is relatively low. Hence, through the above configuration, the number of the first openings 211 can be reduced while ensuring the display quality of the display panel.

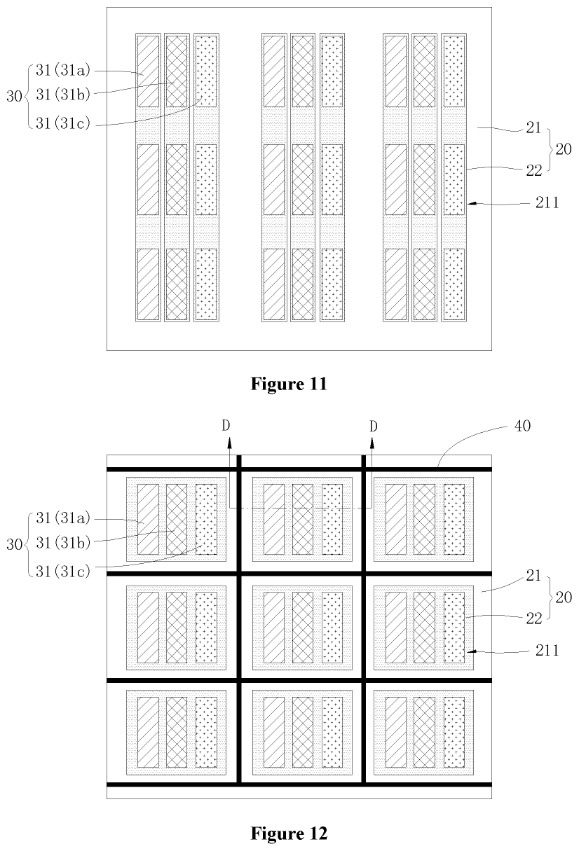

As shown in FIG. 11, in some embodiments, in the display panel according to the embodiment of the present disclosure, the light-emitting elements 31 disposed in the first opening 211 may be configured with the same light-emitting color.

For example, the light-emitting color of the light-emitting elements 31 located in the same first opening 211 may be one red, green and blue. That is, the light-emitting elements 31 located in the same first opening 211 may all be red light-emitting elements, green light-emitting elements or blue light-emitting elements.

In the display panel according to the embodiment of the present disclosure, since the light-emitting elements 31 with the same color has lower requirements for crosstalk rate, the display quality of the display panel can be ensured while reducing the number of the first openings 211, through the above configuration.

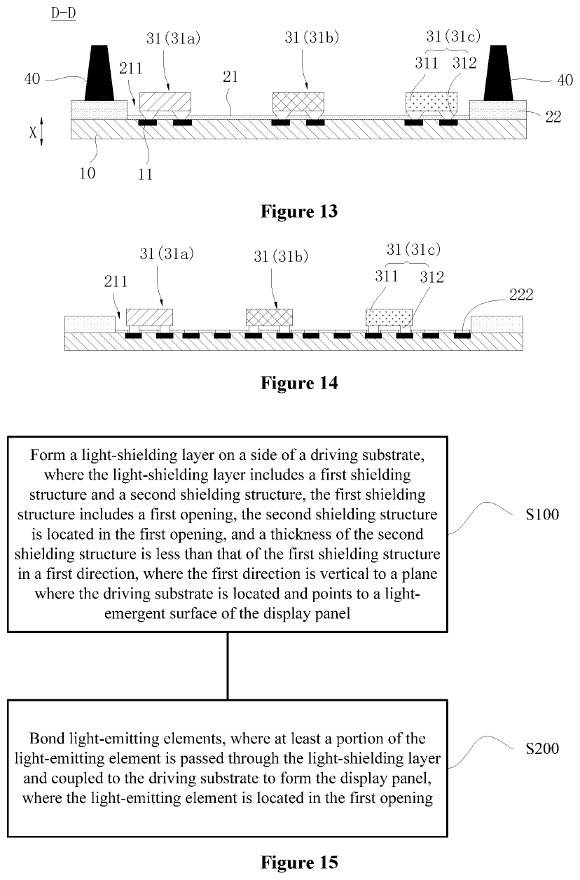

As shown in FIGS. 12 and 13, in some embodiments, the display panel according to the embodiment of the present disclosure further includes: a barrier layer 40. The barrier layer 40 is disposed on a side of the light-shielding layer 20 facing away from the driving substrate 10 and protrudes from the light-emitting element 31 in the first direction X, where adjacent pixel units 30 are separated by the barrier layer 40.

The barrier layer 40 may be disposed surrounding each pixel unit 30. Or, the barrier layer 40 may be disposed surrounding the light-emitting elements 31 with the same color.

In the display panel according to the embodiment of the present disclosure, by configuring the barrier layer 40, the crosstalk between light rays can be further shielded to reduce the optical crosstalk rate of the display panel and optimize the display effect.

In some embodiments, in the display panel according to the embodiment of the present disclosure, the orthographic projection of the barrier layer 40 on the driving substrate in the first direction X is located within the orthographic projection of the first shielding structure 21.

In other words, the barrier layer 40 may be disposed on the first shielding structure 21 and extend along the distribution track of the first shielding structure 21.

In the display panel according to the embodiment of the present disclosure, by disposing the barrier layer 40 on the first shielding structure 21, the probability of crosstalk between the light-emitting elements 31 located in two adjacent first openings 211 can be further reduced, to improve the display quality.

As shown in FIG. 14, in some embodiments, in the display panel according to the embodiment of the present disclosure, at least one light-emitting element 31 is correspondingly provided with a redundant accommodation located in the second shielding structure 22, and the redundant accommodation includes a third opening 222.

The third opening 222 may match the second opening 221 in shape and size.

In the display panel according to the embodiment of the present disclosure, by providing the redundant accommodation in the second shielding structure 22, in a case that the light-emitting element 31 located in the second opening 221 and coupled to the driving substrate 10 is damaged or poorly connected, a light-emitting element 31 can be provided at the third opening 222 and coupled to the driving substrate 10, to replace the light-emitting element 31 that cannot normally emit light at the second opening 221, to meet the display requirements of the display panel.

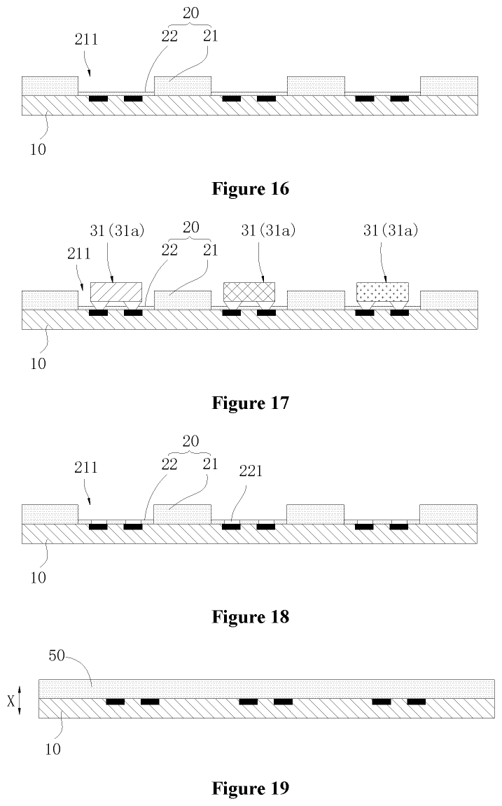

As shown in FIG. 15 to FIG. 17, in another embodiment, a method for manufacturing a display panel is further provided according to the embodiment of the present disclosure, which includes steps S100 and S200 as follows.

In step S100, a light-shielding layer 20 is formed on a side of a driving substrate 10, where the light-shielding layer 20 includes a first shielding structure 21 and a second shielding structure 22, the first shielding structure 21 includes a first opening 211, the second shielding structure 22 is located in the first opening 211, and a thickness of the second shielding structure 22 is less than that of the first shielding structure 21 in a first direction X, where the first direction is vertical to a plane where the driving substrate is located and points to a light-emergent surface of the display panel.

In step S200, light-emitting elements 31 are bonded, where at least a portion of the light-emitting element 33 is passed through the light-shielding layer 20 and coupled to the driving substrate 10 to form the display panel, where the light-emitting element 31 is located in the first opening 211.

In an embodiment, the driving substrate 10 may be prepared on site or prefabricated in advance. Reference may be made to the above description of the display panel for the specific structure of the driving substrate 10, which will not be repeated here.

In an embodiment, when bonding the light-emitting elements 31, there may be no opening provided in the second shielding structure 22 in advance and the light-emitting element 31 can directly pierce through the second shielding structure 22 to be coupled to the driving substrate 10, which is an implementation. In one embodiment, openings may be pre-set in the second shielding structure 22, and the light-emitting elements 31 are directly coupled to the driving substrate 10 through the openings. In one embodiment, the openings may be configured according to the structure of the light-emitting element 31, as long as the bonding requirements can be met.

The method for manufacturing the display panel according to the embodiments of the present disclosure can be used to manufacture the display panel according to the above implementations. The light-shielding layer 20 is first formed on the driving substrate 10 before bonding the light-emitting element 31. The light-shielding layer 20 includes the first shielding structure 21 and second shielding structure 22, the first shielding structure 21 includes a first opening 211, and the second shielding structure 22 is located in the first opening 211. In addition, the thickness of the second shielding structure 22 is less than that of the first shielding structure 21 in a first direction X. In this way, after the light-emitting elements 31 are coupled to the driving substrate 10 to form the display panel, the regions between the light-emitting elements 31 can be light-shielded through the first shielding structure 21, and the regions where the light-emitting elements 31 are located can be light-shielded through the second shielding structure 22, to reduce the overall reflectivity of the display panel and ensuring the display effect.

As shown in FIG. 18, in some embodiments, before the step of bonding the light-emitting elements 31, the method for manufacturing a display panel according to the embodiment of the present disclosure further includes: providing a second opening 221 in the second shielding structure 22.

The number and arrangement of the second openings 221 can be configured according to the second openings 221 in the display panel according to the above embodiments, which will not be repeated here.

In the method for manufacturing the display panel according to the embodiment of the present disclosure, before the step of bonding the light-emitting elements 31, the second opening 221 is provided in the second shielding structure 22. In this way, when the light-emitting elements 31 are bonded to the driving substrate 10, at least a portion of the light-emitting element 31 can directly be passed through the second opening 221 and coupled to the driving substrate 10, reducing the difficulty of bonding.

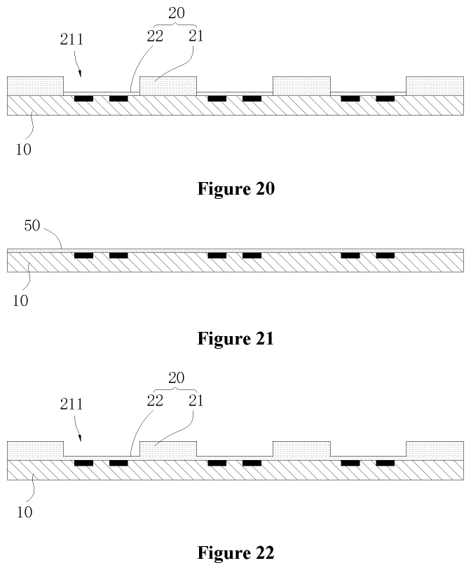

As shown in FIGS. 19 and 20, in some embodiments, in the method for manufacturing a display panel according to the embodiment of the present disclosure, the step of forming the light-shielding layer 20 on a side of the driving substrate 10 includes:
forming a base layer 50 on the driving substrate 10 in the first direction X; and
patterning the base layer 50 to form the light shielding layer 20.

In other words, a thickened base layer 50 may be formed directly on the driving substrate 10, and then patterned, to remove a part of material from the base layer 50 by methods such as etching and the like. The patterned region of the base layer 50 forms the second blocking structures 22, and the un-patterned part forms the first blocking structures 21.

The method for manufacturing a display panel according to the above embodiment of the present disclosure facilitates the formation of the light-shielding layer 20, which satisfies the requirements of the reflective rate of the manufactured display panel.

It can be understood that the above formation method for the light-shielding layer 20 is one embodiment.

As shown in FIG. 21 and FIG. 22, in some embodiments, the step of forming the light-shielding layer 20 on a side of the driving substrate 10 may include:
forming a base layer 50 on the driving substrate 10 in the first direction X; and
forming a thickened layer on a predetermined region of the base layer 50 to form the light-shielding layer 20.

The stacked portions of the thickened layer and the base layer 50 form the first shielding structures 21, and the portions of the base layer 50 without the thickened layer form the second shielding structures 22. The above manufacturing method is also conducive to the formation of the light-shielding layer 20, which satisfies the requirements of the reflective rate of the manufactured display panel.

Further, a display device is further provided according to the present disclosure, which may include the display panel according to the above embodiments. The overall reflectivity of the display device is relatively low with a better display effect.

Although the present disclosure has been described with reference to some embodiments, various modifications may be made and equivalents may be substituted for elements thereof without departing from the scope of the present disclosure. In particular, as long as there is no structural conflict, the features mentioned in the various embodiments can be combined in any manner. The present disclosure is not limited to the some embodiments disclosed herein, rather, includes all solutions falling within the scope of the claims.

What is claimed is:

1. A display panel, comprising:
a driving substrate;
a light-shielding layer, located on a side of the driving substrate, wherein the light-shielding layer comprises a first shielding structure and a second shielding structure, the first shielding structure comprises a first opening, the second shielding structure is located in the first opening, and a thickness of the second shielding structure is less than a thickness of the first shielding structure in a first direction, wherein the first direction is vertical to a plane where the driving substrate is located and points to a light-emergent surface of the display panel; and
a plurality of pixel units, wherein a pixel unit of the plurality of pixel units comprises a plurality of light-emitting elements, wherein a light-emitting element of the plurality of light-emitting elements is located in the first opening, and the driving substrate provides driving signals for the plurality of light-emitting elements.

2. The display panel according to claim 1, wherein the light-emitting element comprises a light-emitting body and a connection terminal, the second shielding structure comprises a second opening, the connection terminal is at least partially disposed in the second opening and is electrically connected to the driving substrate, and the second shielding structure is at least partially disposed between the light-emitting body and the driving substrate.

3. The display panel according to claim 2, wherein the connection terminal has a first end surface and a second end surface opposite to each other in the first direction, the first end surface is connected to the driving substrate, the second end surface is connected to the light-emitting body, and an area of a cross section of the connection terminal increases in the first direction.

4. The display panel according to claim 3, wherein the area of the cross section of the connection terminal increases gradually or in a piecewise manner in the first direction.

5. The display panel according to claim 2, wherein the connection terminal extends in the first direction, a first end surface is connected to the driving substrate, a second end surface is connected to the light-emitting body, and the connection terminal is a structure with a constant cross section from the first end surface to the second end surface in the first direction.

6. The display panel according to claim 2, wherein an aperture diameter of the second opening is equal to an outer diameter of the connection terminal.

7. The display panel according to claim 2, wherein an aperture diameter of the second opening is greater than an outer diameter of the connection terminal, and a gap is formed between an outer peripheral surface of the connection terminal and a wall surface enclosing the second opening.

8. The display panel according to claim 7, wherein the pixel unit comprises a first-color light-emitting element and a second-color light-emitting element, a first gap is formed between the first-color light-emitting element and a wall surface of the seconding opening where the first-color light-emitting element is located, a second gap is formed between the second-color light-emitting element and a wall surface of the seconding opening where the second-color light-emitting element is located, and the first gap is greater than the second gap.

9. The display panel according to claim 2, wherein a ratio of a thickness of the connection terminal to the thickness of the second shielding structure in the first direction is greater than 1.

10. The display panel according to claim 1, wherein a single light-emitting element is disposed in the first opening.

11. The display panel according to claim 10, wherein the pixel unit comprises a first-color light-emitting element, a second-color light-emitting element and a third-color light-emitting element;
in the first direction, a portion of the first shielding structure located between the first-color light-emitting element and the second-color light-emitting element has a first height, and a portion of the first shielding structure located between the second-color light-emitting element and the third-color light-emitting element has a second height, wherein the first height is greater than the second height.

12. The display panel according to claim 1, wherein the display panel has a first region and a second region, and the pixel unit comprises a first-color light-emitting element and a second-color light-emitting element;
in the first region, the first shielding structure between at least one first-color light-emitting element and an adjacent second-color light-emitting element has a third height in the first direction;
in the second region, the first shielding structure between at least one first-color light-emitting element and an adjacent second-color light-emitting element has a fourth height in the first direction; and
the third height is greater than the fourth height.

13. The display panel according to claim 1, wherein at least two light-emitting elements are disposed in the first opening.

14. The display panel according to claim 13, wherein at least two of the light-emitting elements disposed in the first opening have different light-emitting colors; or
the light-emitting elements disposed in the first opening have the same light-emitting color.

15. The display panel according to claim 1, further comprising:
a barrier layer, disposed on a side of the light-shielding layer facing away from the driving substrate and protruding from the light-emitting element in the first direction, wherein adjacent pixel units are separated by the barrier layer.

16. The display panel according to claim 15, wherein an orthographic projection of the barrier layer on the driving substrate is located within an orthographic projection of the first shielding structure in the first direction.

17. A method for manufacturing a display panel, comprising:
forming a light-shielding layer on a side of a driving substrate, where the light-shielding layer comprises a first shielding structure and a second shielding structure, the first shielding structure comprises a first opening, the second shielding structure is located in the first opening, and a thickness of the second shielding structure is less than a thickness of the first shielding structure in a first direction, wherein the first direction is vertical to a plane where the driving substrate is located and points to a light-emergent surface of the display panel; and
bonding light-emitting elements, wherein at least a portion of the light-emitting element is passed through the light-shielding layer and coupled to the driving substrate to form the display panel, wherein the light-emitting element is located in the first opening.

18. The method according to claim 17, where the forming a light-shielding layer on a side of a driving substrate comprises:
forming a base layer on the driving substrate in the first direction; and
patterning the base layer to form the light-shielding layer.

19. The method according to claim 17, wherein the forming a light-shielding layer on a side of a driving substrate comprises:
forming a base layer on the driving substrate in the first direction;
forming a thickened layer on a predetermined region of the base layer to form the light-shielding layer.

20. A display device, comprising a display panel,
wherein the display panel comprises:
a driving substrate;
a light-shielding layer, located on a side of the driving substrate, wherein the light-shielding layer comprises a first shielding structure and a second shielding structure, the first shielding structure comprises a first opening, the second shielding structure is located in the first opening, and a thickness of the second shielding structure is less than a thickness of the first shielding structure in a first direction, wherein the first direction is vertical to a plane where the driving substrate is located and points to a light-emergent surface of the display panel; and
a plurality of pixel units, wherein the pixel unit comprises a plurality of light-emitting elements, the light-emitting element is located in the first opening, and the driving substrate provides driving signals for the light-emitting elements.
